(19) United States
(12) Patent Application Publication
(10) Pub. No.: US 2013/0101372 A1
(43) Pub. Date: Apr. 25, 2013

(54) METHOD AND APPARATUS FOR PROCESSING WAFER-SHAPED ARTICLES

(71) Applicants: Ulrich TSCHINDERLE, FEISTRITZ/GAIL (AT); Andreas GLEISSNER, RADENTHEIN (AT); Thomas WIRNSBERGER, SEEBODEN (AT); Rainer OBWEGER, LIND IM DRAUTAL (AT)

(72) Inventors: Ulrich TSCHINDERLE, FEISTRITZ/GAIL (AT); Andreas GLEISSNER, RADENTHEIN (AT); Thomas WIRNSBERGER, SEEBODEN (AT); Rainer OBWEGER, LIND IM DRAUTAL (AT)

(73) Assignee: LAM RESEARCH AG, VILLACH (AT)

(21) Appl. No.: 13/276,940

(22) Filed: Oct. 19, 2011

(51) Int. Cl. H01L 21/677

(52) U.S. Cl. 414/217; 414/805

(57) ABSTRACT

A device for processing wafer-shaped articles comprises a closed process chamber. The closed process chamber has a side wall, a holder located within the closed process chamber adapted to receive a wafer shaped article, and a door for loading and unloading a wafer shaped article into and from the closed process chamber. The door in a first position blocks an opening in the side wall of the chamber and seals against an interior surface of the side wall of the chamber. The door is connected to an exterior of the chamber via a linkage that guides the door in a nonlinear translational movement between the first position and a second position in which the door is positioned interiorly of the chamber so as to permit loading and unloading of a wafer shaped article through the opening.

### BACKGROUND OF THE INVENTION

1. Field of the Invention

The invention relates generally to a method and apparatus for processing wafer-shaped articles, such as semiconductor wafers, wherein a wafer-shaped article is introduced into and removed from a closed process chamber.

2. Description of Related Art

Semiconductor wafers are subjected to various surface treatment processes such as etching, cleaning, polishing and material deposition. To accommodate such processes, a single wafer may be supported in relation to one or more treatment fluid nozzles by a chuck associated with a rotatable carrier, as is described for example in U.S. Pat. Nos. 4,903,717 and 5,513,668.

Alternatively, a chuck in the form of a ring rotor adapted to support a wafer may be located within a closed process chamber and driven without physical contact through an active magnetic bearing, as is described for example in International Publication No. WO 2007/101764 and U.S. Pat. No. 6,485,531. Treatment fluids which are driven outwardly from the edge of a rotating wafer due to centrifugal action are delivered to a common drain for disposal.

Closed process chambers are used to contain the hazardous substances used for wafer processing, as well as to maintain a superatmospheric pressure for those processes requiring such a condition. However, closed chambers must of course be opened for loading and unloading of wafers. This causes a significant risk that process gas, chemical fumes, hot vapor such as vaporized isopropyl alcohol, ozone and the like could be released to the tool environment, which could result in significant safety risks and damage to surrounding components and tools.

Chamber doors that open outwardly are disadvantageous in that the operator and/or the clean handling area may be exposed to chemical residues deposited on the inside of the door, when the door is opened. Sliding doors make it difficult to form a reliable seal with the surrounding chamber wall, and to maintain a desired overpressure within the chamber. Conventional inwardly opening doors require making the chamber substantially larger to accommodate the door when in the open position.

### SUMMARY OF THE INVENTION

The present inventors have developed an improved closed process chamber for treating wafer-shaped articles, in which an opening for loading and unloading wafer-shaped articles is formed in a side wall of the chamber, with the opening being closed by an inwardly-opening door that, when opened, occupies substantially less space within the chamber than in conventional designs.

Thus, the invention in one aspect relates to a device for processing wafer-shaped articles, comprising a closed process chamber, the closed process chamber comprising a housing having a side wall, a holder located within the closed process chamber adapted to receive a wafer shaped article, and a door for loading and unloading a wafer shaped article into and from the closed process chamber, the door in a first position blocking an opening in the side wall of the chamber and sealing against an interior surface of the side wall of the chamber, and the door being connected to an exterior of the chamber via a linkage that guides the door in a nonlinear translational movement between the first position and a second position in which the door is positioned interiorly of the chamber so as to permit loading and unloading of a wafer shaped article through the opening.

The term translational movement as used herein does not necessarily mean that the closed door position is absolutely parallel to the open door position. The open door position may differ from the closed door position by an angle up to 20° (preferably up to 10°). Moreover, the overall movement of the door may be a combination of nonlinear translation and rotation.

In preferred embodiments of the device according to the present invention, the holder is a rotary chuck adapted to hold a wafer shaped article thereon.

In preferred embodiments of the device according to the present invention, the closed process chamber further comprises an interior cover movable between a first position in which the rotary chuck communicates with the side wall of the closed process chamber, and a second position in which the interior cover seals against an inner surface of the closed process chamber adjacent the rotary chuck to define a gas-tight inner process chamber.

In preferred embodiments of the device according to the present invention, the interior cover forms a lower portion of the inner process chamber when in the second position.

In preferred embodiments of the device according to the present invention, the linkage comprises a pair of pivot arms pivotably mounted at first ends to the exterior of the chamber and pivotably mounted at second ends to an outwardly facing surface of the door.

In preferred embodiments of the device according to the present invention, the first ends of the pair of pivot arms pivot about axes that are parallel but non-coincident to one another, and wherein the second ends of the pair of pivot arms pivot about axes that are parallel but non-coincident to one another.

If the axes corresponding to the first ends of the pair of the pivot arms (the axes proximate the door) and the axes corresponding to the second ends of the pair of the pivot arms (the axes proximate the driving mechanism), have the same distance to one another in the open position as in the closed position, then the door in the open position is parallel to the door in the closed position. If the distance between the axes proximate the door and the axes proximate the drive mechanism is different in the open position than in the closed position, then there is necessarily a rotation component to the movement, in addition to the translational component.

In preferred embodiments of the device according to the present invention, the axes proximate the drive mechanism are located lower that the opening that is covered by the door, and it is also preferred that the drive mechanism itself be mounted at a level lower than the opening that is covered by the door.

This leads to the advantage that even though the door opens inwardly of the chamber, any particles that may be generated by the drive mechanism will be transported downwardly with the downwardly streaming air flow in the clean room that surrounds the chamber.

Particle emission out of the drive mechanism can be further suppressed by providing an additional exhaust to the interior of the drive mechanism in order to provide negative pressure inside the cover.

In preferred embodiments of the device according to the present invention, the nonlinear translational movement has a greater component perpendicular to the side wall as the door approaches the first position, and a greater component parallel to the side wall as the door approaches the second position. If the side wall is vertically oriented the perpendicular component is a horizontal component and the parallel component is vertical.

In preferred embodiments of the device according to the present invention, the linkage comprises at least one arm that is pivotably attached at a distal end to the door, and that is driven in rotation at a proximal end by a motor mounted on the exterior of the closed process chamber.

In preferred embodiments of the device according to the present invention, the linkage comprises a pair of pantographic hinges.

In preferred embodiments of the device according to the present invention, the door has a width that is at least three times its height, preferably at least four times its height, and more preferably at least five times its height.

In preferred embodiments of the device according to the present invention, the door when in the second position is substantially parallel to the side wall and spaced from the interior surface of the side wall of the chamber by a distance no greater than half of its height, preferably no greater than one third of its height.

The invention in another aspect relates to a method of loading or unloading a wafer-shaped article into a device for processing wafer-shaped articles, comprising:

providing a closed process chamber having a side wall and a holder located within the closed process chamber adapted to receive a wafer shaped article;

opening a door for loading and unloading a wafer shaped article into and from the closed process chamber;

guiding the door in a nonlinear translational movement from a first position in which the door blocks an opening in a side wall of the chamber and seals against an interior surface of the side wall of the chamber, and a second position in which the door is positioned interiorly of the chamber; and

loading or unloading a wafer shaped article through the opening.

In preferred embodiments of the method according to the present invention, the holder is a rotary chuck adapted to hold a wafer shaped article thereon.

In preferred embodiments of the method according to the present invention, the door is guided in the nonlinear translational movement via a linkage connected between an outer surface of the door and an exterior of the closed process chamber.

In preferred embodiments of the method according to the present invention, the linkage comprises at least one pantographic hinge.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is an explanatory cross-sectional side view of a process chamber according to a first embodiment of the invention, with the side door shown in its second position and the interior cover shown in its first position;

FIG. 2 is an explanatory cross-sectional side view of a process chamber according to the first embodiment of the invention, with the side door shown in its first position and the interior cover shown in its second position;

FIG. 3 is an enlarged view of the detail III in FIG. 1;

FIG. 4 is an enlarged view of the detail IV in FIG. 2;

FIG. 5 is a perspective view of the side door mechanism of the first embodiment of the invention, as seen from above and outside the process chamber; and

FIG. 6 is a perspective view of the side door mechanism of the first embodiment of the invention, as seen from above and inside the process chamber.

### DETAILED DESCRIPTION OF PREFERRED EMBODIMENTS

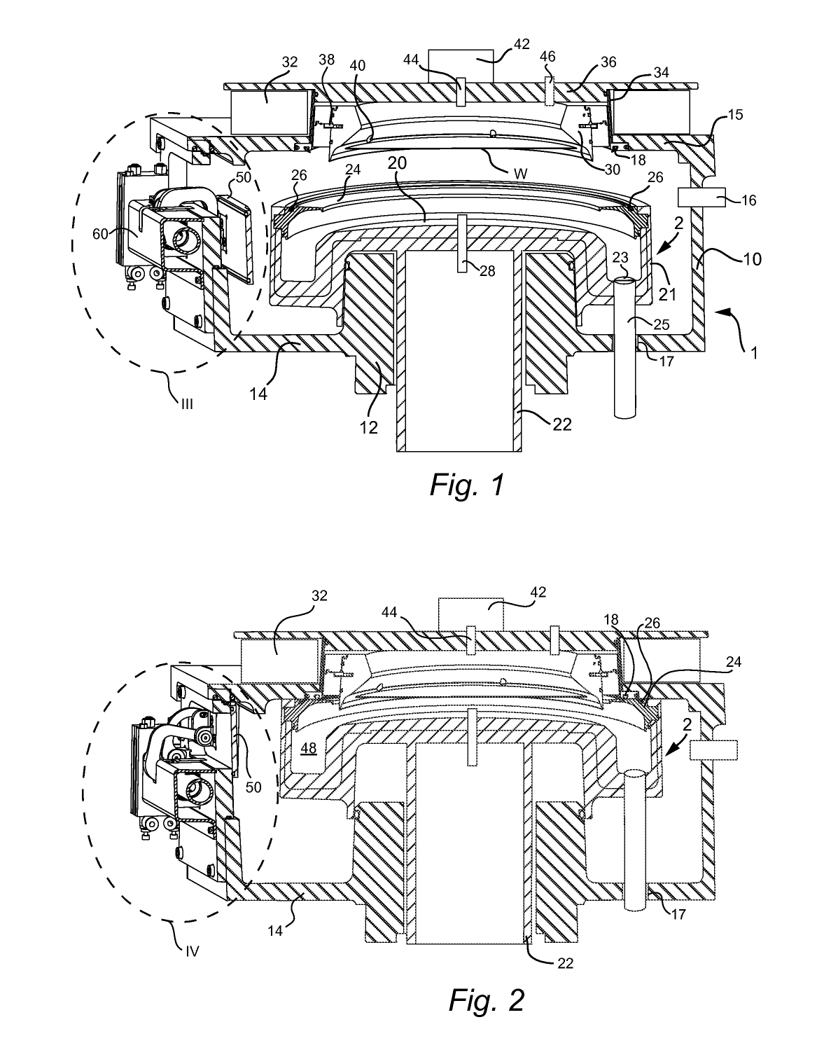

Referring now to FIG. 1, an apparatus for treating surfaces of wafer-shaped articles according to a first embodiment of the invention comprises an outer process chamber 1, which is preferably made of aluminum coated with PFA (perfluoroalkoxy) resin. The chamber in this embodiment has a main cylindrical wall 10, a lower part 12 and an upper part 15. From upper part 15 there extends a narrower cylindrical wall 34, which is closed by a lid 36.

A rotary chuck 30 is disposed in the upper part of chamber 1, and surrounded by the cylindrical wall 34. Rotary chuck 30 rotatably supports a wafer W during used of the apparatus. The rotary chuck 30 incorporates a rotary drive comprising ring gear 38, which engages and drives a plurality of eccentrically movable gripping members for selectively contacting and releasing the peripheral edge of a wafer W.

In this embodiment, the rotary chuck 30 is a ring rotor provided adjacent to the interior surface of the cylindrical wall 34. A stator 32 is provided opposite the ring rotor adjacent the outer surface of the cylindrical wall 34. The rotor 30 and stator 34 serve as a motor by which the ring rotor 30 (and thereby a supported wafer W) may be rotated through an active magnetic bearing. For example, the stator 34 can comprise a plurality of electromagnetic coils or windings that may be actively controlled to rotatably drive the rotary chuck 30 through corresponding permanent magnets provided on the rotor. Axial and radial bearing of the rotary chuck 30 may be accomplished also by active control of the stator or by permanent magnets. Thus, the rotary chuck 30 may be levitated and rotatably driven free from mechanical contact. Alternatively, the rotor may be held by a passive bearing where the magnets of the rotor are held by corresponding high-temperature-superconducting magnets (HTS-magnets) that are circumferentially arranged on an outer rotor outside the chamber. With this alternative embodiment each magnet of the ring rotor is pinned to its corresponding HTS-magnet of the outer rotor. Therefore the inner rotor makes the same movement as the outer rotor without being physically connected.

The lid 36 has a manifold 42 mounted on its exterior, which supplies a medium inlet 44 that traverses the lid 36 and opens into the chamber above the wafer W. It will be noted that the wafer W in this embodiment hangs downwardly from the rotary chuck 30, supported by the gripping members 40, such that fluids supplied through inlet 44 would impinge upon the upwardly facing surface of the wafer W.

In case wafer 30 is a semiconductor wafer, for example of 300 mm or 450 mm diameter, the upwardly facing side of wafer W could be either the device side or the obverse side of the wafer W, which is determined by how the wafer is positioned on the rotary chuck 30, which in turn is dictated by the particular process being performed within the chamber 1.

The apparatus of FIG. 1 further comprises an interior cover 2, which is movable relative to the process chamber 1. Interior cover 2 is shown in FIG. 1 in its first, or open, position, in which the rotary chuck 30 is in communication with the outer cylindrical wall 10 of chamber 1. Cover 2 in this embodiment is generally cup-shaped, comprising a base 20 surrounded by an upstanding cylindrical wall 21. Cover 2 furthermore comprises a hollow shaft 22 supporting the base 20, and traversing the lower wall 14 of the chamber 1.

Hollow shaft 22 is surrounded by a boss 12 formed in the main chamber 1, and these elements are connected via a dynamic seal that permits the hollow shaft 22 to be displaced relative to the boss 12 while maintaining a gas-tight seal with the chamber 1.

At the top of cylindrical wall 21 there is attached an annular deflector member 24, which carries on its upwardly-facing surface a gasket 26. Cover 2 preferably comprises a fluid medium inlet 28 traversing the base 20, so that process fluids and rinsing liquid may be introduced into the chamber onto the downwardly facing surface of wafer W.

Cover 2 furthermore includes a process liquid discharge opening 23, which opens into a discharge pipe 25. Whereas pipe 25 is rigidly mounted to base 20 of cover 2, it traverses the bottom wall 14 of chamber 1 via a dynamic seal 17 so that the pipe may slide axially relative to the bottom wall 14 while maintaining a gas-tight seal.

An exhaust opening 16 traverses the wall 10 of chamber 1, whereas a separate exhaust opening 46 traverses the lid 36 near the inner surface of rotary chuck 30. Each exhaust opening is connected to suitable exhaust conduits (not shown), which are preferably independently controlled via respective valves and venting devices.

The position depicted in FIG. 1 corresponds to loading or unloading of a wafer W. In particular, a wafer W can be loaded onto the rotary chuck 30 through the side door 50, which is shown in its open, or second, position in FIG. 1, so as to permit loading or unloading of a wafer W.

In FIG. 2, the interior cover 2 has been moved to its second, or closed, position, which corresponds to processing of a wafer W. That is, after a wafer W is loaded onto rotary chuck 30, the door 50 is moved to its closed, or first, position as shown in FIG. 2, and the cover 2 is moved upwardly relative to chamber 1, by a suitable motor (not shown) acting upon the hollow shaft 22. The upward movement of the interior cover 2 continues until the deflector member 24 comes into contact with the interior surface of the upper part 15 of chamber 1. In particular, the gasket 26 carried by deflector 24 seals against the underside of upper part 15, whereas the gasket 18 carried by the upper part 15 seals against the upper surface of deflector 24.

When the interior cover 2 reaches its second position as depicted in FIG. 2, there is thus created a second chamber 48 within the closed process chamber 1. Inner chamber 48 is moreover sealed in a gas tight manner from the remainder of the chamber 1. Moreover, the chamber 48 is preferably separately vented from the remainder of chamber 1, which is achieved in this embodiment by the provision of the exhaust port 46 opening into the chamber 48, independently from the exhaust port 16 that serves the chamber 1 in general, and the remainder of the chamber 1 in the FIG. 2 configuration.

During processing of a wafer, processing fluids may be directed through medium inlets 44 and/or 28 to a rotating wafer W in order to perform various processes, such as etching, cleaning, rinsing, and any other desired surface treatment of the wafer undergoing processing.

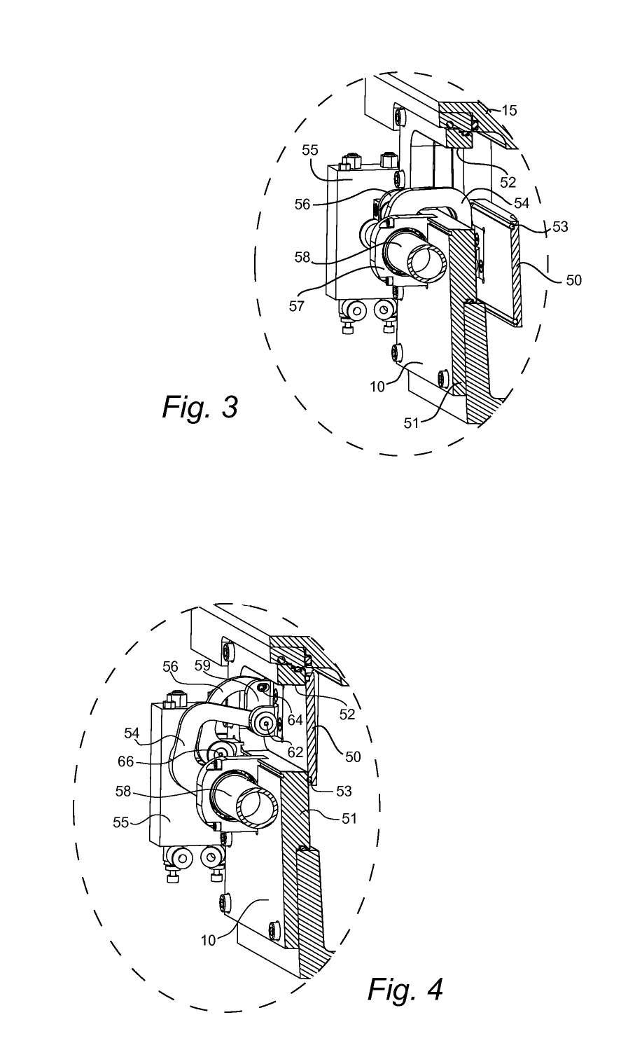

Referring now to FIGS. 3 and 4, the structure and mechanism of the side door 50 will be described in greater detail. In these figures, the cover 60 shown in FIGS. 1 and 2 has been removed for ease of understanding. When the door 50 is in its open, or second, position as shown in FIG. 3, the door 50 is located entirely within the interior space of the outer chamber 1. Door 50 comprises a gasket 53 along the periphery of its outwardly-facing side, and which seals against an interior surface of the side wall 10 when the door 50 is closed.

Side wall 10 in this embodiment comprises a mounting plate 51 on which the opening and closing mechanism for the door 50 may be mounted. That mechanism in this embodiment comprises a pneumatic motor 55 that drives a shaft 58 in rotation over an angular range corresponding to the movement of the door 50 between its open and closed positions.

Shaft 58 is rotatably supported by a pair of brackets 57 mounted on plate 51, with one bracket 57 positioned near each end of shaft 58. Only one bracket 57 is visible in FIGS. 3 and 4, as the section of these figures is taken approximately half way along the length of shaft 58. Door 50 is connected to shaft 58 by an approximately U-shaped arm 54, with a proximal end of the arm 54 being keyed to shaft 58 and a distal end of arm 54 being pivotably mounted to the door 50. A follower arm 56 is also pivotably mounted at its distal end to the door 50, whereas its proximal end is mounted for pivotal motion in a secondary bracket about an axis parallel to and offset from the axis of rotation of shaft 58.

Opening 52 is formed in plate 51 to permit loading and unloading of a wafer-shaped article onto the chuck 30, when the door 50 is in its open position as depicted in FIG. 3. If the wafer shaped article is a 300 mm semiconductor wafer, then the width of opening 52 will be slightly greater than 300 mm. The width of opening 52 is preferably at least three times its height, and preferably at least five times its height. Thus, in the case of a 300 mm semiconductor wafer, opening 52 will have a height that is preferably not greater than 100 mm, and preferably not greater than 60 mm.

Referring now to FIG. 4, the door 50 has been moved to its closed, or first, position, as occurs after a wafer-shaped article W has been loaded into or removed from the chamber 1. In particular, pneumatic motor 55 has been actuated to move shaft 58 over its range of angular motion, which in this embodiment is approximately 80°. The gasket 53 seated in the outwardly-facing surface of door 50 is now seated against the interior of side wall 10/plate 51, in the region surrounding opening 52.

The door may be seated in its closed position by the action of the pneumatic motor 55, and/or by any overpressure within the chamber 1. Door 50 can preferably withstand an overpressure of at least 2 bar. The design of door 50 as a plug door in this respect contributes to its ability to withstand elevated pressures within chamber 1.

In FIG. 4 bracket 59 is visible, which is rigidly mounted to the outwardly-facing surface of door 50. The distal ends of arms 54 and 56 are pivotally mounted to the bracket 59 at pivot points 62 and 64, respectively, and, in the case of the follower arm 56, its distal end is preferably accommodated in a slot in the bracket 59 so as to allow a limited range of sliding movement as well.

The proximal end of the follower arm 56 is pivotally mounted to a secondary bracket at 66, and thus the proximal and distal ends of the follower arm 56 pivot about axes that are parallel to and offset from the respective axes of rotation of the proximal and distal ends of the main arm 54.

Arms 54 and 56, as well as brackets 57 and 59, are preferably duplicated close to the other end of shaft 58, which as noted above is not visible in these figures. A second motor 55 may also be provided at the opposite end of shaft 58.

In comparing FIGS. 3 and 4, it will be seen that the opening and closing mechanism of the side door 50 causes the door 50 to undergo a translation movement along a nonlinear path, as it is moved between its first and second positions.

Moreover, the shape of arm(s) 54 causes the movement of door 50 to have a greater horizontal component just as the door 50 is removed from the closed position shown in FIG. 4; however, as the opening of the door 50 continues, the vertical component of its motion continuously increases, such that, as the door 50 approaches the position depicted in FIG. 3, its movement may be almost entirely or entirely vertical, and thus parallel to the side wall 10.

Indeed, depending upon the particular shape and mounting of arm(s) 54, it is possibly that door 50 will, in the course of moving from its closed to open position, reach its position of maximum inward displacement before arriving at the position depicted in FIG. 3, and thereafter move slightly outwardly until the position depicted in FIG. 3 is reached.

From FIG. 3 it will be appreciated that the side door according to the present embodiment intrudes upon the interior volume of chamber 1 to a much lesser extent than in conventional designs. In particular, the side door when in its fully open position is substantially parallel to the side wall of chamber 1, and is spaced from the interior surface of side wall 10 by a distance no greater than half of its height, and preferably no greater than one third of its height.

In an alternative embodiment, motor(s) 55 may be omitted and shaft 58 may be freely rotatable within brackets 57. In that case, the pairs of arms 54 and 56 will guide the door 50 along the same nonlinear translational path, in the manner of pantographic hinges. A latch could be provided to hold the door 50 loosely in its first position, until chamber overpressure serves to seat the gasket 53 firmly against the interior surface of side wall 10/plate 51.

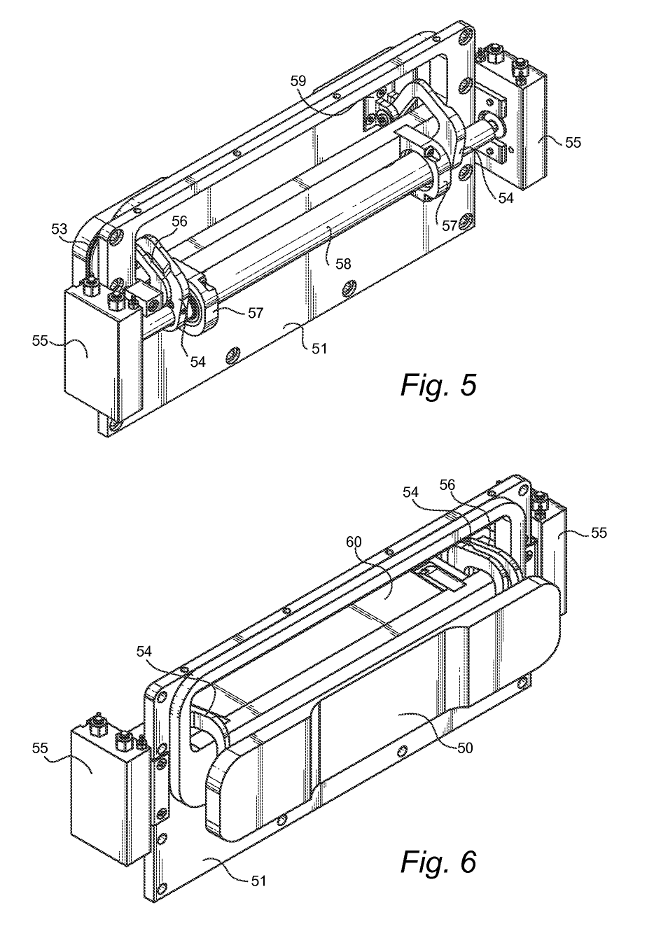

In FIGS. 5 and 6, the full door mechanism is shown. Here, a pair of motors 55 is provided as well as a pair of the brackets 57 and 59. However, whereas two arms 54 are provided, only one arm 56 is provided, as in practice a single follower arm will often be sufficient to ensure that the door 50 remains substantially parallel to the chamber side wall 10 thought the range of motion of door 50.

Door 50 and arms 54, 56 are preferably formed from a material that is resistant to the high temperatures and highly corrosive materials that may be utilized within the process chamber. For example, the arms may be formed of a plastic such as polyetheretherketone (PEEK), and door 50 may be formed from a highly temperature and chemical resistant polyimide resin such as those sold under the trade name VESPEL®.

What is claimed is:

1. Device for processing wafer-shaped articles, comprising a closed process chamber, said closed process chamber comprising a housing having a side wall, a holder located within the closed process chamber adapted to receive a wafer shaped article, and a door for loading and unloading a wafer shaped article into and from said closed process chamber, said door in a first position blocking an opening in said side wall of said chamber and sealing against an interior surface of said side wall of said chamber, and said door being connected to an exterior of said chamber via a linkage that guides said door in a nonlinear movement between said first position and a second position in which said door is positioned interiorly of said chamber so as to permit loading and unloading of a wafer shaped article through said opening.

2. The device according to claim 1, wherein said closed process chamber further comprises an interior cover movable between a first position in which said holder communicates with said side wall of said closed process chamber, and a second position in which said interior cover seals against an inner surface of said closed process chamber adjacent said rotary chuck to define a gas-tight inner process chamber.

3. The device according to claim 1, wherein said interior cover forms a lower portion of said inner process chamber when in said second position.

4. The device according to claim 1, wherein said linkage comprises a pair of pivot arms pivotably mounted at first ends to the exterior of said chamber and pivotably mounted at second ends to an outwardly facing surface of said door.

5. The device according to claim 5, the first ends of said pair of pivot arms pivot about axes that are parallel but non-coincident to one another, and wherein the second ends of said pair of pivot arms pivot about axes that are parallel but non-coincident to one another.

6. The device according to claim 1, wherein the drive mechanism of the door is located lower than the opening that is covered with the door.

7. The device according to claim 1, wherein said nonlinear translational movement has a greater component perpendicular to said side wall as said door approaches said first position, and a greater component parallel to said side wall as said door approaches said second position.

8. The device according to claim 1, wherein said linkage comprises at least one arm that is pivotably attached at a distal end to said door, and that is driven in rotation at a proximal end by a motor mounted on the exterior of said closed process chamber.

9. The device according to claim 1, wherein said linkage comprises a pair of pantographic hinges.

10. The device according to claim 1, wherein said door has a width that is at least three times its height, preferably at least four times its height, and more preferably at least five times its height.

11. The device according to claim 1, wherein said door when in the second position is substantially parallel to said side wall and spaced from said interior surface of said side wall of said chamber by a distance no greater than half of its height, preferably no greater than one third of its height.

12. A method of loading or unloading a wafer-shaped article into a device for processing wafer-shaped articles, comprising:
providing a closed process chamber having a side wall and a holder located within the closed process chamber adapted to receive a wafer shaped article;
opening a door for loading and unloading a wafer shaped article into and from the closed process chamber;
guiding the door in a nonlinear translational movement from a first position in which the door blocks an opening in a side wall of the chamber and seals against an interior surface of the side wall of the chamber, and a second position in which the door is positioned interiorly of the chamber; and
loading or unloading a wafer shaped article through the opening.

13. The process according to claim 12, wherein the holder is a rotary chuck adapted to hold a wafer shaped article thereon.

14. The process according to claim 12, wherein the door is guided in the nonlinear translational movement via a linkage connected between an outer surface of the door and an exterior of the closed process chamber.

15. The process according to claim 14, wherein the linkage comprises at least one pantographic hinge.
